(19) United States
(12) Patent Application Publication
(10) Pub. No.: US 2016/0016310 A1
(43) Pub. Date: Jan. 21, 2016

(54) NOTCH FILTER, EXTERNAL FORCE ESTIMATOR, MOTOR CONTROL APPARATUS, AND ROBOTIC SYSTEM

(71) Applicant: KABUSHIKI KAISHA YASKAWA DENKI, Kitakyushu-shi (JP)

(72) Inventors: Fei ZHAO, Kitakyushu-shi (JP); Takashi MAMBA, Kitakyushu-shi (JP)

(73) Assignee: KABUSHIKI KAISHA YASKAWA DENKI, Kitakyushu-shi (JP)

(21) Appl. No.: 14/864,876

(22) Filed: Sep. 25, 2015

Related U.S. Application Data
(63) Continuation of application No. PCT/JP2013/058994, filed on Mar. 27, 2013.

(51) Int. Cl. B25J 9/16; H03H 21/00; G05B 13/02; H02P 29/00

(52) U.S. Cl. CPC B25J 9/1633; H02P 29/0038; H03H 21/0021; G05B 13/0205; Y10S 901/09

(57) ABSTRACT

A notch filter includes: an attenuation filter configured to acquire a signal containing a vibrational component generated in association with movement of a motor to perform attenuation of the vibrational component; and an attenuation controller configured to control an attenuation amount in the attenuation, corresponding to a movement speed of the motor.

### CROSS-REFERENCE TO RELATED APPLICATION

The present application is a continuation application of International Application No. PCT/JP2013/058994 filed on Mar. 27, 2013, the entire content of which is hereby incorporated by reference.

### BACKGROUND

1. Technical Field

Embodiments of the disclosure relate to a notch filter, an external force estimator, a motor control apparatus, and a robotic system.

2. Description of the Related Art

Typically, for example, in the field of robots, an external force torque applied to a motor is estimated using an external force estimator (see JP-A-2001-353687).

### SUMMARY

A notch filter includes: an attenuation filter configured to acquire a signal containing a vibrational component generated in association with movement of a motor to perform attenuation of the vibrational component; and an attenuation controller configured to control an attenuation amount in the attenuation, corresponding to a movement speed of the motor.

### BRIEF DESCRIPTION OF THE DRAWINGS

FIG. 1 is a diagram illustrating one example of a robot to which a robotic system according to a first embodiment is applied;

FIG. 2 is a block diagram illustrating the configuration of the robotic system according to the first embodiment;

FIG. 3 is a block diagram illustrating a configuration example of an external force observer;

FIG. 4 is a block diagram illustrating the configuration of a notch filter according to the first embodiment;

FIG. 5A is a graph illustrating frequency characteristics of a notch filter according to the first embodiment;

FIG. 5B is a graph illustrating frequency characteristics of the notch filter according to the first embodiment;

FIG. 6A is a graph illustrating one example of the relationship between a notch center frequency and a notch depth;

FIG. 6B is a graph illustrating one example of the relationship between the notch center frequency and the notch depth;

FIG. 6C is a graph illustrating one example of the relationship between the notch center frequency and the notch depth;

FIG. 7A is a graph illustrating frequency characteristics of a notch filter according to a second embodiment;

FIG. 7B is a graph illustrating frequency characteristics of the notch filter according to the second embodiment;

FIG. 8 is a block diagram illustrating the configuration of a robotic system according to a third embodiment;

FIG. 9 is a block diagram illustrating the configuration of a robotic system according to a fourth embodiment;

FIG. 10 is a block diagram illustrating a configuration example of an external force observer according to the fourth embodiment; and

FIG. 11 is a block diagram illustrating the configuration of a robotic system according to a fifth embodiment.

### DESCRIPTION OF THE EMBODIMENTS

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A notch filter according to one aspect of the embodiments includes an attenuation filter and an attenuation controller. The attenuation filter acquires a signal containing a vibrational component generated in association with the movement (for example, rotation or translation) of a motor, so as to perform attenuation of the vibrational component. The attenuation controller controls the attenuation amount in the attenuation corresponding to the movement speed (for example, a rotation speed or a translational speed) of the motor.

According to the one aspect of the embodiments, it is possible to attenuate the vibrational component generated in association with the movement (for example, rotation or translation) of the motor.

The following describes embodiments of a notch filter, an external force estimator, a motor control apparatus, and a robotic system, which are disclosed in the present application, in detail with reference to the attached drawings. Note that no embodiment described below limits the technique of the present disclosure.

### First Embodiment

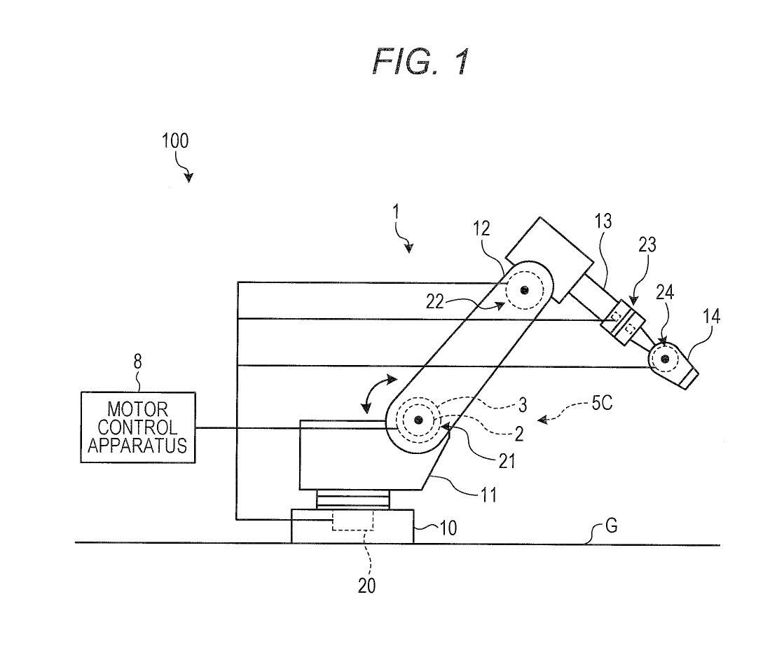

FIG. 1 is a diagram illustrating one example of a robot 1 to which a robotic system 100 according to a first embodiment is applied.

As illustrated in FIG. 1, the robot 1 includes a base 10, a body 11, a first arm portion 12, a second arm portion 13, and a wrist portion 14.

The base 10 is fixedly secured to an installation surface G. The body 11 is mounted on the base 10 to be turnable in the horizontal direction via a turning portion 20. The first arm portion 12 couples to the body 11 to be swingable via a first joint portion 21. The second arm portion 13 couples to the first arm portion 12 to be swingable via a second joint portion 22. The wrist portion 14 couples to the second arm portion 13 to be axially rotatable via a third joint portion 23 and swingable via a fourth joint portion 24. The tip portion of the wrist portion 14 couples to an end effector (not illustrated) corresponding to the usage as necessary.

The turning portion 20 and the first to fourth joint portions 21 to 24 incorporate actuators 50, which drive the body 11, the first arm portion 12, the second arm portion 13, and the wrist portion 14 as movable parts. Specifically, as illustrated in FIG. 1, the actuator 50 includes a motor 2 and a reducer 3.

The motor 2 electrically couples to a motor control apparatus 8, which controls the driving of the motor 2, and drives in accordance with the command output from the motor control apparatus 8. The reducer 3 couples to the output shaft of the motor 2, and reduces the rotation of the output shaft of the motor 2 so as to transmit the reduced rotation to the movable parts such as the first arm portion 12. The motor control apparatus 8 is, for example, a servo amplifier, a controller that controls the servo amplifier, or a control apparatus that includes a servo amplifier and a controller.

The first embodiment employs a harmonic reducer as the reducer 3. The harmonic reducer is a reducer (strain wave gearing) using the differential motion between an ellipse and a true circle. This harmonic reducer has the property that vibrates twice every one rotation of the output shaft of the motor 2. This point will be described later.

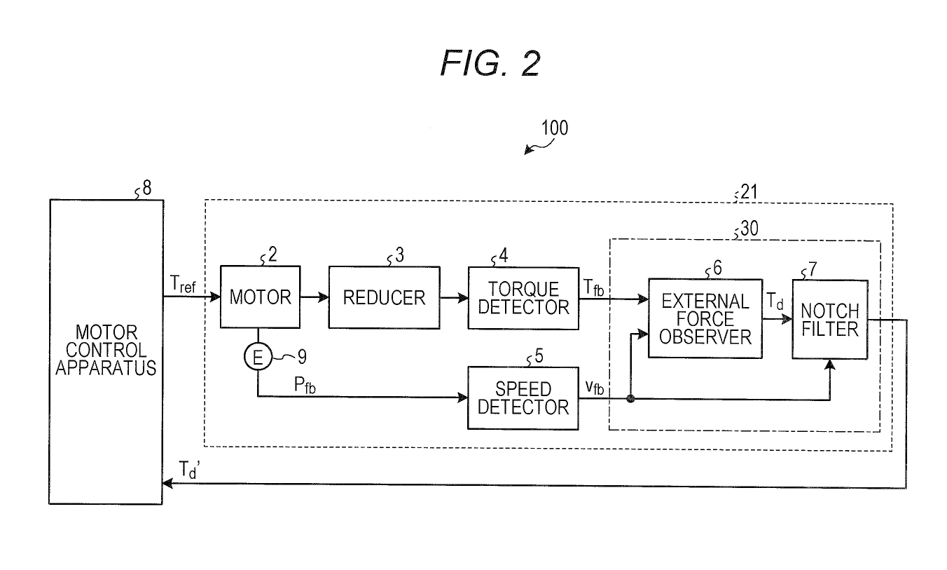

The following specifically describes the configuration of the robotic system 100 with reference to FIG. 2. FIG. 2 is a block diagram illustrating the configuration of the robotic system 100 according to the first embodiment. In FIG. 2, the configuration of the first joint portion 21 will be described as an example. The turning portion 20 and the second to fourth joint portions 22 to 24 also have similar configurations.

As illustrated in FIG. 2, the robotic system 100 includes the first joint portion 21 and an external force estimator 30. The first joint portion 21 includes, in addition to the motor 2 and the reducer 3 described above, a torque detector 4, a speed detector 5, and a position detector 9. The external force estimator 30 is disposed inside the first joint portion 21.

The torque detector 4 is disposed between the reducer 3 and a load (here, the first arm portion 12), and detects the torque (N·m) when the motor 2 drives.

The position detector 9 is, for example, an encoder, and detects a rotation position P_{fb} of the output shaft of the motor 2 so as to output the rotation position P_{fb} to the speed detector 5. Here, the encoder is an absolute value encoder in this embodiment. However, the encoder as the position detector 9 is not limited to this, but may be an incremental encoder. Instead of the encoder, the position detector 9 may employ a resolver or the like.

The speed detector 5 performs a difference operation on the rotation position P_{fb} input from the position detector 9 so as to detect the rotation speed (rad/s) of the output shaft of the motor 2. Here, the method for detecting the torque by the torque detector 4 and the method for detecting the rotation speed by the speed detector 5 may employ respective publicly-known techniques.

Here, in this embodiment, the motor 2, the reducer 3, the torque detector 4, the speed detector 5, and the position detector 9 are mutually separated bodies. Alternatively, for example, it is possible to employ a reducer-integrated motor, a sensor-integrated motor, or a sensor-integrated reducer. Alternatively, it is possible to employ a sensor-integrated actuator that integrally includes the motor 2, the reducer 3, the torque detector 4, the speed detector 5, and the position detector 9.

For example, in the example of the robotic system 100, the external force estimator 30 estimates an external force acting on such as the first arm portion 12 and/or the second arm portion 13. Specifically, the external force estimator 30 includes an external force observer 6 and a notch filter 7. The external force observer 6 estimates an external force torque applied around the output shaft of the motor 2, based on a torque detection value T_{fb} which is output from the torque detector 4, and a speed detection value v_{fb} which is output from the speed detector 5. Here, in this embodiment, the information related to a movement force, a torque, or a translational force can correspond to the torque detection value T_{fb}. The information related to a movement speed, a rotation speed, or a translational speed can correspond to the speed detection value v_{fb}.

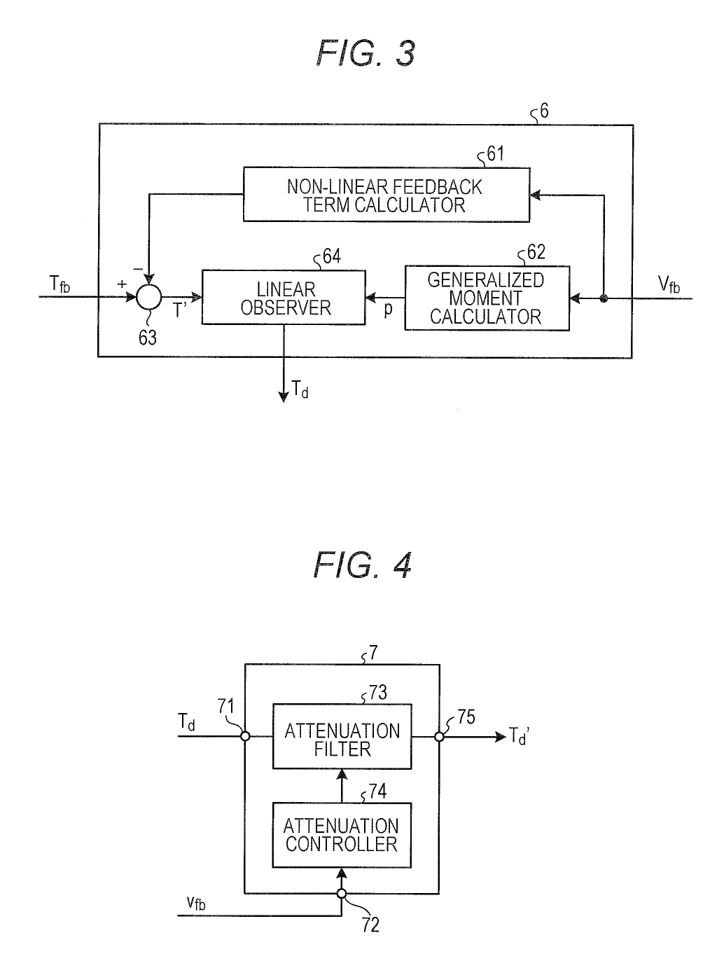

Here, a description will be given of one example of a specific configuration of the external force observer 6 with reference to FIG. 3. FIG. 3 is a block diagram illustrating a configuration example of the external force observer 6.

As illustrated in FIG. 3, the external force observer 6 includes a non-linear feedback term calculator 61, a generalized moment calculator 62, a subtractor 63, and a linear observer 64.

The non-linear feedback term calculator 61 uses the rotation position P_{fb} and the speed detection value v_{fb} to calculate a non-linear feedback term. Here, the non-linear feedback term calculated by the non-linear feedback term calculator 61 is expressed by the following formula (1).

$$C ( q , \frac{d }{d t} q ) \frac{d }{d t} q + g ( q ) - \frac{d }{d t} ( M ( q ) ) \frac{d }{d t} q \qquad ( 1 )$$

Here, q corresponds to the rotation position P_{fb}, and dq/dt corresponds to the speed detection value v_{fb}. Additionally, C(q, dq/dt) is a matrix related to a centrifugal force and a Coriolis force, g(q) is a gravity term, and M(q) is a mass matrix of a link. The non-linear feedback term calculator 61 outputs the calculated non-linear feedback term to the subtractor 63.

The generalized moment calculator 62 uses the rotation position P_{fb} and the speed detection value v_{fb} to calculate a generalized moment p and output the generalized moment p to the linear observer 64. Here, p=M(q) dq/dt.

Here, in this embodiment, the non-linear feedback term calculator 61 and the generalized moment calculator 62 each calculate the rotation position P_{fb} from the speed detection value v_{fb} acquired from the speed detector 5. Alternatively, the non-linear feedback term calculator 61 and the generalized moment calculator 62 may each acquire the rotation position P_{fb} from the position detector 9.

The subtractor 63 subtracts the non-linear feedback term from the torque detection value T_{fb} so as to obtain a value T′. The subtractor 63 outputs the obtained value T′ to the linear observer 64.

The linear observer 64 is a general linear observer. The linear observer 64 uses the generalized moment p, which is input from the generalized moment calculator 62, and the value T′, which is input from the subtractor 63, to calculate an external-force estimated value T_{d}.

Here, as described above, the reducer 3 as the harmonic reducer vibrates twice every one rotation of the output shaft of the motor 2. This vibration of the reducer 3 is detected as a torque by the torque detector 4. Accordingly, the torque detection value T_{fb} vibrates, and the external-force estimated value T_{d} vibrates in association with this vibration of the torque detection value T_{fb}.

Thus, the external-force estimated value T_{d} contains a vibrational component generated in association with the rotation of the motor 2, specifically, a vibrational component generated by vibration of the reducer 3 in association with the rotation of the motor 2. Therefore, the robot 1 according to the first embodiment attenuates this vibrational component using the notch filter 7, so as to improve the accuracy of the external-force estimated value.

The configuration of this notch filter 7 will be described with reference to FIG. 4. FIG. 4 is a block diagram illustrating the configuration of the notch filter 7 according to the first embodiment.

As illustrated in FIG. 4, the notch filter 7 includes a first input unit 71, a second input unit 72, an attenuation filter 73, an attenuation controller 74, and an output unit 75. Here, in this embodiment, the attenuation filter 73 and the attenuation controller 74 can respectively correspond to means for filtering and means for controlling an attenuation amount of the attenuation.

The first input unit 71 receives an input of the external-force estimated value T_{d}. The second input unit 72 receives an input of the speed detection value v_{fb}. The output unit 75 outputs an external-force estimated value T_{d}′, where the vibrational component is attenuated by the attenuation filter 73 described later. Here, the first input unit 71, the second input unit 72, and the output unit 75 correspond to, for example, ports, terminals, or nodes.

The attenuation filter 73 attenuates the vibrational component contained in the external-force estimated value T_{d} input from the first input unit 71. In the case where the notch filter 7 is a digital filter, a transfer function G (s) of the attenuation filter 73 is expressed by the following formula (2).

$$\frac{{s}^{2} + 2 {δζω}_{n} s + {ω}_{n}^{2}}{{s}^{2} + 2 {ζω}_{n} s + {ω}_{n}^{2}} \qquad ( 2 )$$

Here, δ is a parameter that determines the attenuation amount (hereinafter referred to as a “notch depth”) of the vibrational component. Also, ζ is a parameter that determines the width (hereinafter referred to as a “notch width”) of the attenuation band. Also, ωₙ is a parameter that determines the center frequency (hereinafter referred to as a “notch center frequency”) of the attenuation band.

Additionally, assuming that ν is the notch depth, δ, which is the parameter determining the notch depth, is expressed by the following formula (3).

$$δ = {10}^{- \frac{v}{20}} \qquad ( 3 )$$

The attenuation controller 74 receives an input of the speed detection value v_{fb}, from the second input unit 72. The attenuation controller 74 controls the notch center frequency ωₙ of the attenuation filter 73 corresponding to the input speed detection value v_{fb}. Specifically, the attenuation controller 74 increases and decreases the notch center frequency ωₙ of the attenuation filter 73 corresponding to an increase and a decrease in speed detection value v_{fb}. This allows the attenuation filter 73 to appropriately attenuate the vibrational component having a frequency that changes corresponding to the rotation speed of the motor 2.

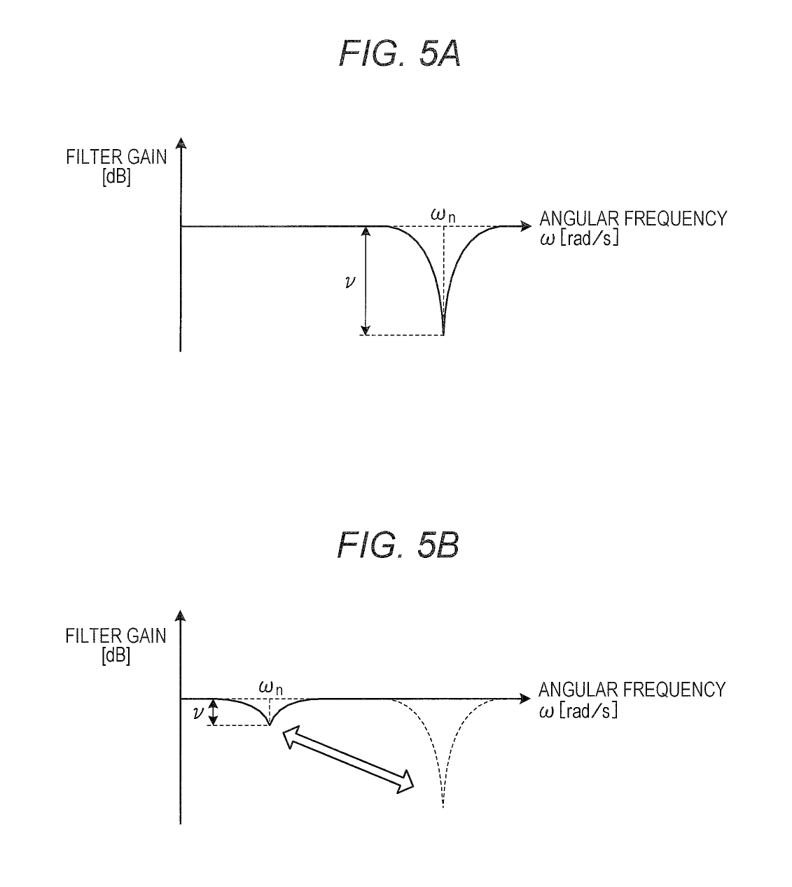

This point will be described with reference to FIGS. 5A and 5B. FIGS. 5A and 5B are graphs illustrating frequency characteristics of the notch filter 7 according to the first embodiment. As illustrated in FIG. 5A, the attenuation filter 73 attenuates a predetermined frequency band of the input signal. Here, ωₙ is a notch center frequency, and ν is a notch depth.

As described above, the reducer 3 as the harmonic reducer vibrates twice every one rotation of the output shaft of the motor 2. In other words, the reducer 3 vibrates at double the frequency of the rotation speed of the motor 2. Accordingly, the vibrational component contained in the external-force estimated value T_{d} has a higher frequency as the rotation speed of the motor 2 becomes faster.

Therefore, as illustrated in FIG. 5B, the attenuation controller 74 increases the notch center frequency ωₙ of the attenuation filter 73 as the speed detection value v_{fb} input from the second input unit 72 becomes higher. On the other hand, the attenuation controller 74 decreases the notch center frequency ωₙ of the attenuation filter 73 as the speed detection value v_{fb} becomes lower. Specifically, the notch center frequency ωₙ is ωₙ=2v_{fb}.

Thus, in the first embodiment, focusing on the situation where the frequency of the vibration of the reducer 3 increases and decreases corresponding to the rotation speed of the motor 2, the attenuation band of the attenuation filter 73 is moved corresponding to the speed detection value v_{fb}. Specifically, the reducer 3 vibrates at double the frequency of the rotation speed of the motor 2. Accordingly, the attenuation controller 74 changes (sets) the notch center frequency ωₙ to double the frequency of the speed detection value v_{fb}. This allows appropriately attenuating the vibrational component contained in the external-force estimated value T_{d}. As a result, the accuracy of the external-force estimated value can be improved.

Furthermore, the attenuation controller 74 also increases and decreases the notch depth ν corresponding to an increase and a decrease in speed detection value v_{fb} input from the second input unit 72. The following describes this point.

As described above, the vibration of the reducer 3 has a higher frequency as the rotation speed of the motor 2 increases. On the other hand, the amplitude is approximately constant regardless of the rotation speed of the motor 2. Despite this, the notch filter 7 according to the first embodiment shallows the notch depth ν, that is, reduces the attenuation amount of the vibrational component of the external-force estimated value T_{d} when the rotation speed of the motor 2 is slow, that is, the vibration of the reducer 3 has a low frequency.

This is because effective information is concentrated on a low frequency band of the external-force estimated value T_{d}. Intentionally reducing the attenuation amount of the vibrational component in the low frequency band allows keeping the effective information contained in the external-force estimated value T_{d} and attenuating an unnecessary vibrational component.

Specifically, as illustrated in FIG. 5B, the attenuation controller 74 shallows the notch depth ν of the attenuation filter 73 as the notch center frequency ωₙ decreases, that is, the speed detection value v_{fb} input from the second input unit 72 decreases.

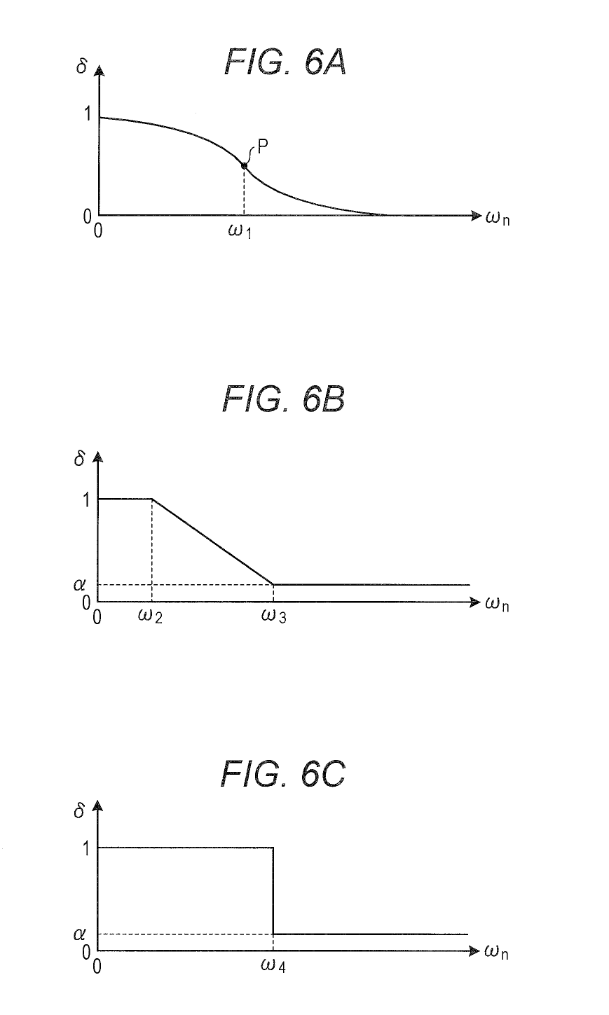

Next, a description will be given of one example of the method for changing the notch depth ν with reference to FIGS. 6A to 6C. FIGS. 6A to 6C are graphs illustrating examples of the relationship between the notch center frequency ωₙ and the notch depth ν.

Here, FIGS. 6A to 6C illustrate the relationships between ωₙ and δ in the case where the horizontal axis denotes the notch center frequency ωₙ and the vertical axis denotes δ as the parameter determining the notch depth ν. As apparent from the above-described formula (3), the notch depth ν becomes 0 when δ is 1, and the notch depth ν becomes infinity when δ is 0.

For example, as illustrated in FIG. 6A, the attenuation controller 74 may control the attenuation amount in the attenuation by the attenuation filter 73 such that δ decreases along a curved line in association with an increase in ωₙ (that is, in association with an increase in speed detection value v_{fb}) assuming that δ=1 when ωₙ=0. The curved line illustrated in FIG. 6A is a curved line (a sigmoid curve) having an inflection point P when ωₙ=ω1, and is convex upward when ωₙ<ω1 while being convex downward when ωₙ>ω1.

Here, the curved line is not limited to the line illustrated in FIG. 6A, but the attenuation controller 74 may control the attenuation amount in the attenuation by the attenuation filter 73 such that δ decreases along a curved line (for example, an exponential curve) without any inflection point.

As illustrated in FIG. 6B, two threshold values ω₂ and ω₃ may be provided. In this case, the attenuation controller 74 may control the attenuation amount of the attenuation filter 73 so as to: set δ to be constant in the state where δ=1 when ωₙ≦ω₂; set δ to be constant in the state where δ=a(<1) when ωₙ≧ω₃; and linearly decrease δ from 1 to a in association with an increase in ωₙ when ω₂<ωₙ<ω₃.

That is, the attenuation controller 74 may control the attenuation amount of the attenuation filter 73 so as to: set the notch depth ν to 0 in the case where the speed detection value v_{fb} equal to or less than ω₂/2 (a first threshold value) is input; and set the notch depth ν to a constant amount larger than 0 irrespective of the speed detection value v_{fb} in the case where the speed detection value v_{fb} equal to or more than ω₃/2 (a second threshold value) is input.

In the above-described example, the attenuation controller 74 sets the notch depth ν to be constant in the case where the speed detection value v_{fb}, equal to or more than a predetermined threshold value (here, ω₃/2) is input. This is originally because the amplitude of the vibration of the reducer 3 in association with the rotation of the motor 2 is approximately constant irrespective of the rotation speed of the motor 2. Thus, setting the notch depth ν at a rotation speed equal to or more than ω₃/2 to be constant allows reducing the processing load compared with the case illustrated in FIG. 6A.

Here, in the example illustrated in FIG. 6B, the attenuation controller 74 linearly decreases δ in association with an increase in ωₙ when ω₂<ωₙ<ω₃. Alternatively, the attenuation controller 74 may decrease δ along a curved line in association with an increase in w when ω₂<ₙ<ω₃. In the example illustrated in FIG. 6B, two threshold values are set. Alternatively, three or more threshold values may be set.

As illustrated in FIG. 6C, one threshold value 107 ₙ may be provided. In this case, the attenuation controller 74 may control the attenuation amount of the attenuation filter 73 so as to: set δ to be constant in the state where δ=1 (that is, ν=0) when ωₙ<ω₄; and set δ to be constant in the state where δ=a (>0) irrespective of the speed detection value v_{fb} when ωₙ≧ω₄.

For example, the part of 0≦ωₙ<ω₃ in FIG. 6B may be replaced by the curved line illustrated in FIG. 6A. That is, the attenuation controller 74 may control the attenuation amount of the attenuation filter 73 so as to: decrease δ along the curved line illustrated in FIG. 6A when 0≦ωₙ<ω₃; and set δ to be constant in the state where δ=a when ωₙ≧ω₃.

As illustrated in FIG. 2, the external-force estimated value T_{d}′, which is output from the external force estimator 30, after filtering is fed back to the motor control apparatus 8. Then, the motor control apparatus 8 corrects a torque command based on this external-force estimated value T_{d}′ so as to output a corrected torque command T_{ref} to the motor 2.

For example, the motor control apparatus 8 performs positive feedback that causes outputting, as the torque command T_{ref}, the value obtained by subtracting the external-force estimated value T_{d}′ from the torque command before the correction. Alternatively, the motor control apparatus 8 may perform negative feedback that causes inverting the phase of the external-force estimated value T_{d}′ so as to output, as the torque command T_{ref}, the value obtained by subtracting the external-force estimated value T_{d}′ after the phase inversion from the torque command before the correction. This allows the motor control apparatus 8 to accurately perform the control of the robot 1.

As described above, the robotic system 100 according to the first embodiment includes the robot 1, the external force observer 6, and the notch filter 7. The robot 1 is configured such that the turning portion 20 and the respective joint portions 21 to 24 include the motor 2 and the reducer 3. The external force observer 6 generates the external-force estimated value T_{d} based on the torque detection value Tₜₕ and the speed detection value v_{fb} of the motor 2. The notch filter 7 attenuates the vibrational component, which is caused by the rotation of the motor 2, contained in the external-force estimated value T_{d} output from the external force observer 6. The notch filter 7 includes the attenuation filter 73 and the attenuation controller 74. The attenuation filter 73 acquires the external-force estimated value T_{d} to perform the attenuation of the vibrational component contained in the external-force estimated value T_{d}. The attenuation controller 74 acquires the speed detection value v_{fb} of the motor 2 to control the attenuation amount in the attenuation by the attenuation filter 73 corresponding to the acquired speed detection value v_{fb}.

Accordingly, the robotic system 100 according to the first embodiment allows attenuating the vibrational component caused in association with the rotation of the motor 2.

In the robotic system 100 according to the first embodiment, the attenuation filter 73 acquires the external-force estimated value T_{d} containing the vibrational component generated by the vibration of the reducer 3 in association with the rotation of the motor 2. This allows the attenuation filter 73 to attenuate the vibrational component in the external-force estimated value T_{d,} the component being generated by the vibration of the reducer 3 in association with the rotation of the motor 2.

Here, in this embodiment, a description has been given of the example of the case where the notch center frequency ωₙ is double the speed detection value v_{fb} when the reducer 3 has the property that vibrates twice every one rotation of the output shaft of the motor 2. Similarly, the notch center frequency ωₙ only needs to be n times (n is an integer equal to or more than 2) as large as the speed detection value v_{fb} when the reducer 3 has the property that vibrates n times every one rotation of the output shaft of the motor 2. The value of n described above is not limited to an integer equal to or more than 2. That is, the notch center frequency ωₙ only needs to be three-halves the speed detection value v_{fb} when the reducer 3 has the property that vibrates three times every two rotations of the output shaft of the motor 2. Alternatively, the notch center frequency ωₙ only needs to be one-third the speed detection value v_{fb} when the reducer 3 has the property that vibrates once every three rotations of the output shaft of the motor 2. Thus, the attenuation controller 74 may be configured to change the notch center frequency ωₙ to a frequency proportional to the speed detection value v_{fb}.

In this embodiment, a description has been given of the example of the case where the reducer 3 is a reducer that vibrates corresponding to the rotation speed of the motor 2 (that is, the case where the vibrational component of the external-force estimated value T_{d} changes corresponding to the rotation speed of the motor 2). Alternatively, the reducer 3 may be a reducer that vibrates independently of the rotation speed of the motor 2. Also in this case, the notch filter 7 described above can be used to appropriately attenuate the vibrational component of the external-force estimated value T_{d} in the case where the vibration (that is, the vibrational component of the external-force estimated value T_{d}) of the reducer 3 changes corresponding to the rotation of the motor 2.

### Second Embodiment

In the above-described first embodiment, a description has been given of the example of the case where the notch center frequency ωₙ and the notch depth ν are both increased and decreased corresponding to an increase and a decrease in rotation speed of the motor 2. Alternatively, the notch filter 7 may be configured to fix the notch center frequency ωₙ to increase and decrease the notch depth ν alone.

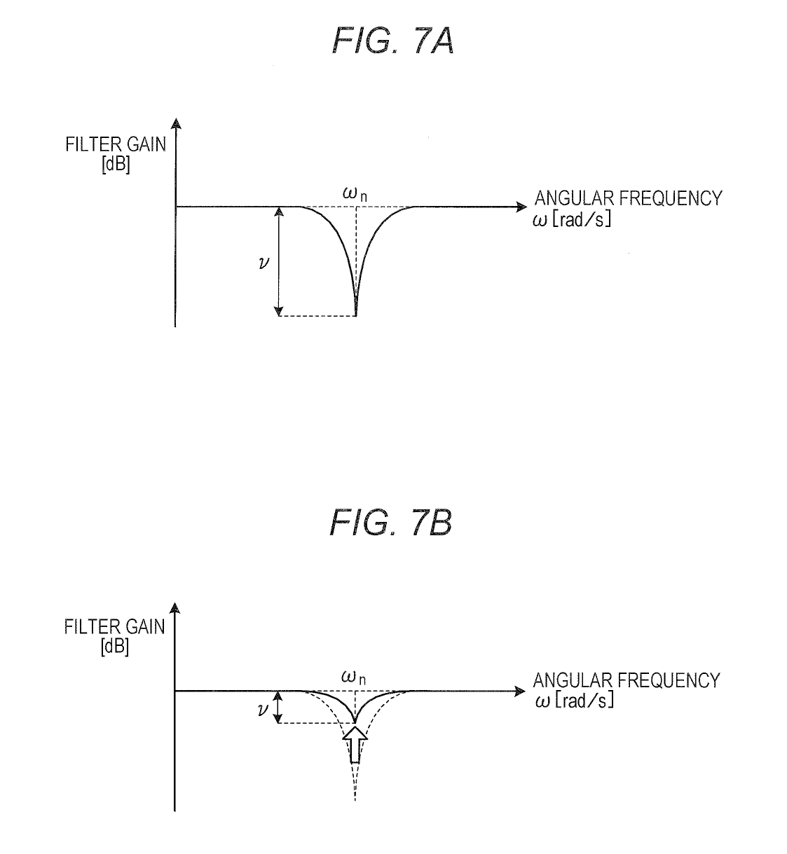

This point will be described with reference to FIGS. 7A and 7B. FIGS. 7A and 7B are graphs illustrating frequency characteristics of the notch filter 7 according to a second embodiment.

As illustrated in FIGS. 7A and 7B, the attenuation controller 74 of the notch filter 7 according to the second embodiment changes the notch depth ν without changing the notch center frequency ωₙ in the case where the speed detection value v_{fb} input from the second input unit 72 changes. For example, the notch depth ν may be expressed by ν=kv_{fb} using a predetermined coefficient k (k is a positive number), or may be a predetermined function ν=f(v_{fb}) where the speed detection value v_{fb} is set as a variable.

In the first embodiment, a description has been given of the case where the reducer 3 is a harmonic reducer as an example. However, in the case where the reducer 3 is a reducer other than the harmonic reducer, the amplitude of the vibration of the reducer 3, that is, the amplitude of the vibrational component of the external-force estimated value T_{d} might increase and decrease in association with an increase and a decrease in rotation speed of the motor 2 depending on the type of the reducer.

In this case, like the notch filter 7 according to the second embodiment, the notch depth ν can be increased and decreased corresponding to an increase and a decrease in speed detection value v_{fb} so as to attenuate the vibrational component generated in association with the rotation of the motor 2.

### Third Embodiment

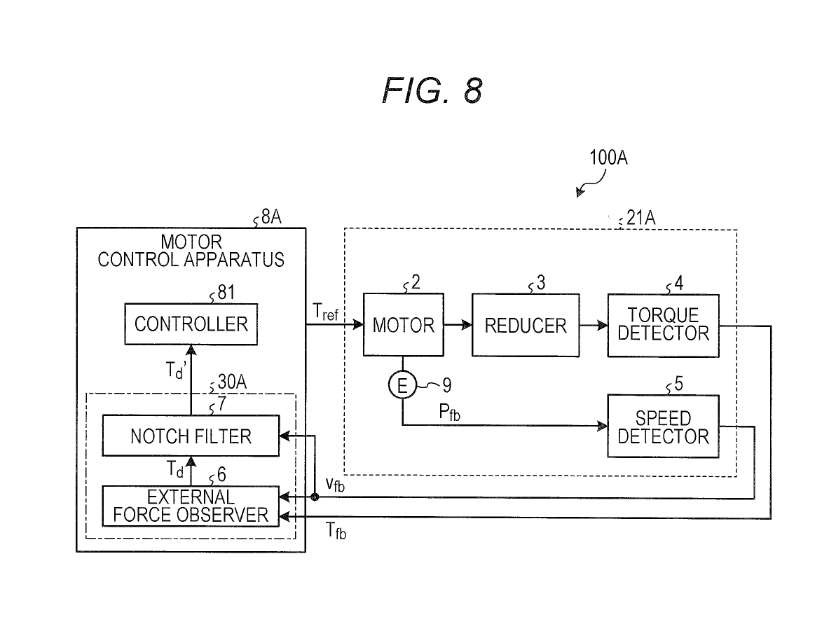

Incidentally, in the respective embodiments described above, a description has been given of the examples of the case where the external force estimator 30 is disposed in the turning portion 20 and the first to fourth joint portions 21 to 24. Alternatively, the external force estimator 30 may be, for example, disposed in the motor control apparatus 8. The following describes the example of the case where the motor control apparatus includes a processor corresponding to the external force estimator 30 with reference to FIG. 8. FIG. 8 is a block diagram illustrating the configuration of a robotic system according to a third embodiment.

As illustrated in FIG. 8, in a robotic system 100A according to the third embodiment, a first joint portion 21A has the configuration excluding the external force estimator 30 from the first joint portion 21 according to the first and second embodiments. Other joint portions and turning portions similarly have the configurations excluding the external force estimator 30.

A motor control apparatus 8A according to the third embodiment includes an external force estimating unit 30A and a controller 81. The external force estimating unit 30A is a processor corresponding to the external force estimator 30, and includes the external force observer 6 and the notch filter 7 similarly to the external force estimator 30. Here, the motor control apparatus 8A includes a plurality of the external force estimating units 30A corresponding to the respective joint portions and turning portions. FIG. 8 illustrates the external force estimating unit 30A corresponding to the first joint portion 21A. The controller 81 controls, for example, the motor 2 based on the signal (the external-force estimated value T_{d}′), where the vibrational component is attenuated, output from the attenuation filter 73 of the notch filter 7.

The torque detection value T_{fb} and the speed detection value v_{fb} are input to the external force estimating unit 30A disposed in the motor control apparatus 8A. Specifically, the torque detection value T_{fb} is input to the external force observer 6, and the speed detection value v_{fb} is input to both the external force observer 6 and the notch filter 7.

In the external force estimating unit 30A, similarly to the external force estimator 30 described above, the external force observer 6 generates the external-force estimated value T_{d} based on the torque detection value T_{fb} and the speed detection value v_{fb} to output the external-force estimated value T_{d} to the notch filter 7. Furthermore, the notch filter 7 attenuates the vibrational component of the external-force estimated value T_{d} to generate the external-force estimated value T_{d}′ so as to output the external-force estimated value T_{d}′ to the controller 81. As described in the first and second embodiments, the notch filter 7 includes the attenuation filter 73 and the attenuation controller 74 (see FIG. 4). In the notch filter 7, the attenuation controller 74 changes the notch center frequency ωₙ and/or the notch depth ν of the attenuation filter 73 corresponding to the speed detection value v_{fb}. This allows the notch filter 7 to attenuate the vibrational component, which is generated in association with the rotation of the motor 2, contained in the external-force estimated value T_{d}.

The controller 81 corrects a torque command based on the external-force estimated value T_{d}′ input from the external force estimating unit 30A to output the corrected torque command T_{ref} to the motor 2.

Thus, the attenuation filter 73 and the attenuation controller 74 may be disposed in the motor control apparatus 8A.

In the respective embodiments described above, a description has been given of the examples of the case where the notch filter 7 is disposed in the external force estimator 30 or the external force estimating unit 30A. Alternatively, the notch filter 7 may be separated from the external force observer 6 and disposed in any position inside the control loop illustrated in FIG. 2.

The input signal input to the notch filter 7 only needs to be a signal containing the vibrational component generated in association with the rotation of the motor 2, and is not limited to the external-force estimated value T_{d}. For example, the notch filter 7 may be disposed in the subsequent stage of the torque detector 4. In this case, the vibrational component contained in the torque detection value T_{fb} may be attenuated by the notch filter 7.

### Fourth Embodiment

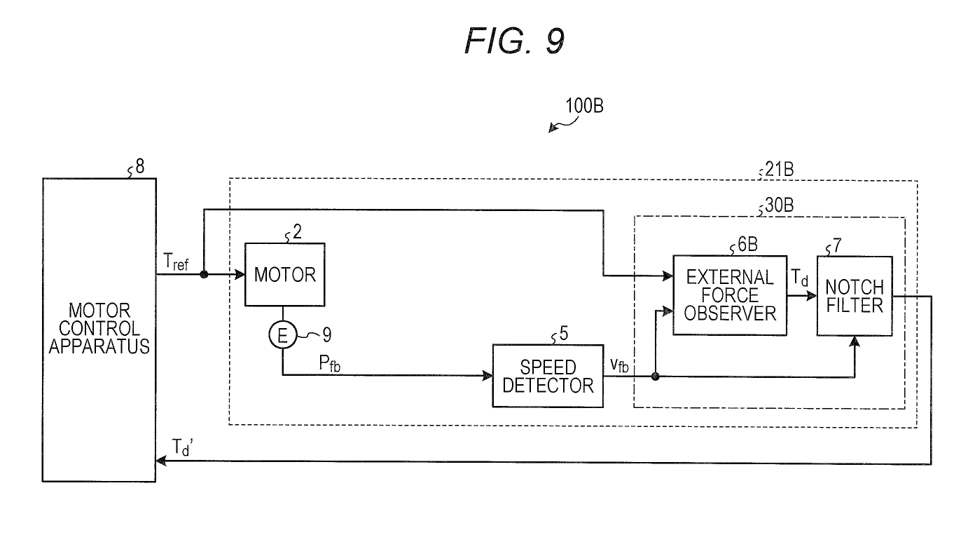

The following describes the configuration of a robotic system according to a fourth embodiment with reference to FIG. 9. FIG. 9 is a block diagram illustrating the configuration of the robotic system according to the fourth embodiment.

As illustrated in FIG. 9, a first joint portion 21B included in a robotic system 100B according to the fourth embodiment has the configuration excluding the reducer 3 and the torque detector 4 from the first joint portion 21 (see FIG. 2) according to the first embodiment.

In the respective embodiments as described above, a description has been given of the examples of the case where the reducer 3 generates the vibrational component of the signal (for example, the torque detection value T_{fb} or the external-force estimated value Td). However, the source of generation of the vibrational component is not only the reducer 3. For example, the vibrational component might be generated due to the structure of the motor 2 itself. That is, also in the system without the reducer 3 like the robotic system 100B according to the fourth embodiment, the vibrational component generated in association with the rotation of the motor 2 might be contained in the external-force estimated value T_{d}. The robotic system 100B allows attenuating the vibrational component generated in association with the rotation of the motor 2 also in the case of the application to this system.

Unlike the external force observer 6 described above, an external force observer 6B according to the fourth embodiment estimates the external-force estimated value T_{d} using the torque command T_{ref} output from the motor control apparatus 8. In this case, the external force observer 6B estimates, as an “external force,” the sum of external forces, the frictional forces, and other forces acting on the first arm portion 12 and the like, that is, disturbances.

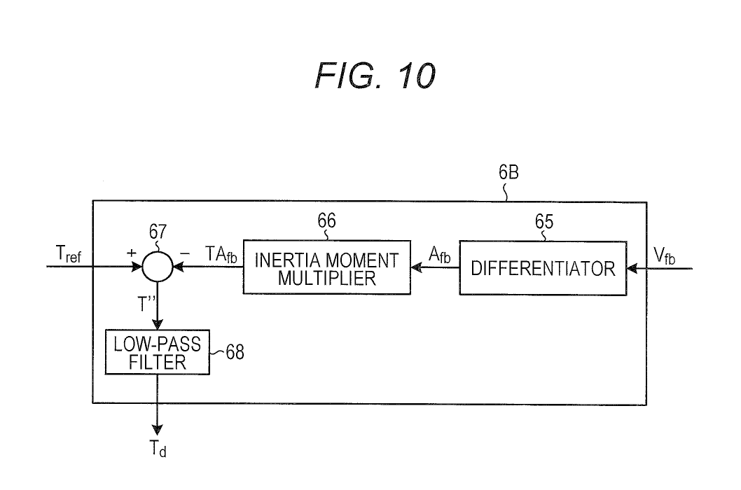

Here, a description will be given of a configuration example of the external force observer 6B according to the fourth embodiment with reference to FIG. 10. FIG. 10 is a block diagram illustrating the configuration example of the external force observer 6B according to the fourth embodiment. As illustrated in FIG. 10, the external force observer 6B includes a differentiator 65, an inertia moment multiplier 66, a subtractor 67, and a low-pass filter 68.

The differentiator 65 differentiates the speed detection value v_{fb} so as to calculate an acceleration detection value A_{fb} and outputs the calculated acceleration detection value A_{fb} to the inertia moment multiplier 66. The inertia moment multiplier 66 multiplies the acceleration detection value A_{fb}, which is input from the differentiator 65, by the inertia moment around the motor shaft so as to calculate an accelerating-torque detection value TA_{fb}. The inertia moment multiplier 66 outputs the calculated accelerating-torque detection value TA_{fb} to the subtractor 67.

The subtractor 67 subtracts the torque command T_{ref} from the accelerating-torque detection value TA_{fb} so as to obtain a value T″. The subtractor 67 outputs the obtained value T″ to the low-pass filter 68. The low-pass filter 68 outputs the value obtained by applying a low-pass filter to T″ as the external-force estimated value T_{d}.

Similarly to the first or second embodiment, the notch filter 7 acquires the external-force estimated value T_{d} and attenuates the vibrational component contained in the external-force estimated value T_{d} so as to generate the external-force estimated value T_{d}′ and output the external-force estimated value T_{d}′ to the motor control apparatus 8.

Thus, the external force observer 6B may calculate the external-force estimated value T_{d} using the torque command T_{ref} instead of the torque detection value T_{fb}.

Here, in this embodiment, a description has been given of the example of the case where an external force estimator 30B is disposed in the first joint portion 21B. Alternatively, similarly to the third embodiment, a processor corresponding to the external force estimator 30B may be disposed in the motor control apparatus 8 instead of the external force estimator 30B.

### Fifth Embodiment

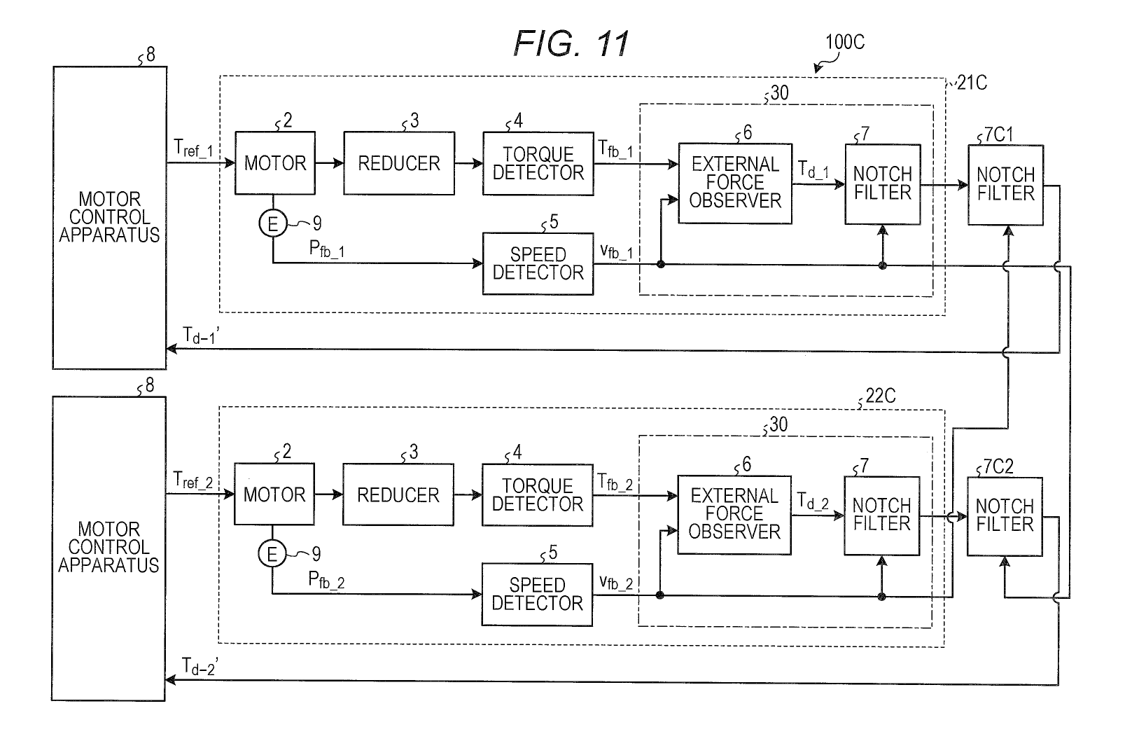

The following describes the configuration of a robotic system according to a fifth embodiment with reference to FIG. 11. FIG. 11 is a block diagram illustrating the configuration of the robotic system according to the fifth embodiment.

As illustrated in FIG. 11, a robotic system 100C according to the fifth embodiment further includes notch filters 7C1 and 7C2. The notch filter 7C1 is disposed in the subsequent stage of the notch filter 7 in a first joint portion 21C. The notch filter 7C2 is disposed in the subsequent stage of the notch filter 7 in a second joint portion 22C. In this embodiment, the subsequent-stage notch filter can correspond to the notch filters 7C1 and 7C2.

The first joint portion 21C and the second joint portion 22C have configurations similar to that of the first joint portion 21 according to the first embodiment described above. Hereinafter, assume that the torque command, the rotation position, the torque detection value, the speed detection value, and the external-force estimated value for the first joint portion 21C are respectively “T_{ref}_{_{—}}₁,” “P_{tb}_{_{—}}₁,” “T_{fb}_{_{—}}₁,” “v_{fb}_{_{—}}₁,” and “T_{d}_{_{—}}₁(T_{d}_{_{—}}₁′”. Assume that, for the second joint portion 22C, the respective values are “T_{ref}_{_{—}}₂,” “P_{fb}_{_{—}}₂,” “T_{fb}_{_{—}}₂,” “v_{fb}_{_{—}}₂,” and “T_{d}_{_{—}}₂(T_{d}_{_{—}}₂′).”

Here, in the first joint portion 21C, the signal of the first joint portion 21C can also contain the vibrational component (that is, the vibrational component of the signal of the first joint portion 21C to be generated due to the vibration in another system, for example, the vibrational component of the signal of the first joint portion 21C to be generated in association with the rotation of the motor in another system) generated in another system (such as the second joint portion 22C) inside the robotic system 100C. This is similar in the second joint portion 22C.

Therefore, the robotic system 100C according to the fifth embodiment further includes the notch filters 7C1 and 7C2 so as to attenuate the vibrational component generated in another system using the notch filters 7C1 and 7C2.

For example, the notch filter 7C1 receives an input of the external-force estimated value output from the notch filter 7 of the first joint portion 21C, that is: the external-force estimated value where vibrational component due to the vibration of the reducer 3 of the first joint portion 21C is attenuated; and the speed detection value v_{fb}_{_{—}}₂ output from the speed detector 5 of the second joint portion 22C. The notch filter 7C1 filters the external-force estimated value output from the notch filter 7 of the first joint portion 21C using the notch center frequency ωₙ and the notch depth ν corresponding to the speed detection value v_{fb}_{_{—}}₂. This allows the notch filter 7C1 to attenuate the vibrational component, which is generated in the second joint portion 22C, contained in the external-force estimated value output from the notch filter 7 of the first joint portion 21C. The external-force estimated value T_{d}_{_{—}}₁′ after filtering is output to the motor control apparatus 8.

The notch filter 7C2 receives an input of the external-force estimated value output from the notch filter 7 of the second joint portion 22C, that is: the external-force estimated value where the vibrational component due to the vibration of the reducer 3 of the second joint portion 22C is attenuated; and the speed detection value v_{fb}_{_{—}}₁ output from the speed detector 5 of the first joint portion 21C. The notch filter 7C2 filters the external-force estimated value output from the notch filter 7 of the second joint portion 22C using the notch center frequency ωₙ and the notch depth ν corresponding to the speed detection value v_{fb}_{_{—}}₁. This allows the notch filter 7C2 to attenuate the vibrational component, which is generated in the first joint portion 21C, contained in the external-force estimated value output from the notch filter 7 of the second joint portion 22C. The external-force estimated value T_{d}_{_{—}}₂′ after filtering is output to the motor control apparatus 8.

Thus, the robotic system 100C according to the fifth embodiment further includes the notch filters 7C1 and 7C2 so as to allow attenuating the vibrational component generated in another system.

That is, in the robotic system 100C according to the fifth embodiment, the robot 1 includes the first joint portion 21C and the second joint portion 22C as a plurality of joint portions. These first joint portion 21C and second joint portion 22C each include the external force observer 6 and the notch filter 7. The robotic system 100C includes the notch filters 7C1 and 7C2.

The notch filter 7C1 is disposed in the subsequent stage of the notch filter 7 in the first joint portion 21C. The notch filter 7C1 attenuates the vibrational component that is generated in association with the rotation of the motor 2 of the second joint portion 22C and contained in the signal output from the notch filter 7 of the first joint portion 21C.

The notch filter 7C2 is disposed in the subsequent stage of the notch filter 7 in the second joint portion 22C. The notch filter 7C2 attenuates the vibrational component that is generated in association with the rotation of the motor 2 of the first joint portion 21C and contained in the signal output from the notch filter 7 of the second joint portion 22C.

Here, in this embodiment, a description has been given of the example of the case where the notch filter 7C1 for attenuating the vibrational component generated in the second joint portion 22C is disposed in the subsequent stage of the notch filter 7 of the first joint portion 21C. However, the configuration is not limited to this, and a notch filter that attenuates the vibrational component generated in a joint portion other than the second joint portion 22C may be further disposed in the subsequent stage of the notch filter 7 in addition to the notch filter 7C1.

In this embodiment, a description has been given of the example of the case where the notch filters 7C1 and 7C2 are disposed outside the first joint portion 21C and the second joint portion 22C. Alternatively, the notch filters 7C1 and 7C2 may be respectively disposed inside the first joint portion 21C and the second joint portion 22C or may be disposed inside the motor control apparatus 8.

Similarly to the third embodiment, the external force estimator 30 may be excluded from the first joint portion 21C and the second joint portion 22C while a processor corresponding to the external force estimator 30 is disposed in the motor control apparatus 8.

Similarly to the fourth embodiment, the external force observer 6 may calculate the external-force estimated value T_{d} using the torque command T_{ref} instead of the torque detection value T_{fb}.

The motor 2 is not limited to a rotary motor, but may be a direct acting type linear motor. In this case, the translational force corresponds to the torque described above while the translational speed corresponds to the rotation speed described above. That is, the attenuation filter 73 may be configured to acquire the signal (for example, the external-force estimated value T_{d} or the torque detection value T_{fb}) containing the vibrational component generated in association with the movement (for example, the rotation or the translation) of the motor, so as to perform the attenuation of the vibrational component of this signal. Furthermore, the attenuation controller 74 may be configured to control the attenuation amount in the attenuation by the attenuation filter 73, corresponding to the movement speed (for example, the rotation speed or the translational speed) of the motor.

The external force observer 6 may be configured to generate the external-force estimated value T_{d} based on: the information related to the movement force (for example, the torque or the translational force), of the motor; and the information related to the movement speed (for example, the rotation speed or the translational speed), of the motor.

In the case where the motor 2 is a direct acting type linear motor, the attenuation filter 73 may be configured to acquire the signal (for example, the external-force estimated value T_{d} or the torque detection value T_{fb}) containing the vibrational component generated in association with the translation of the linear motor as the motor 2, so as to perform the attenuation of the vibrational component of this signal. Furthermore, the attenuation controller 74 may be configured to control the attenuation amount in the attenuation by the attenuation filter 73, corresponding to the translational speed of the motor 2.

The motor 2 is not limited to an electric motor, but may be a fluid pressure actuator or the like.

In the respective embodiments described above, a description has been given of the examples where the external force estimator 30 is applied to the robot 1. However, the configuration of the robot to which the external force estimator 30 is applied is not limited to that illustrated in FIG. 1. The external force estimator 30 can be applied to not only the robot 1, but any configuration driven by the motor 2.

Additional effects and modifications will readily occur to those skilled in the art. Therefore, the disclosure in its broader aspects is not limited to the specific details and representative embodiments shown and described herein. Accordingly, various modifications may be made without departing from the spirit or scope of the general technical concept as defined by the appended claims and their equivalents.

The embodiments of this disclosure may be the following first to ninth notch filters, first external force estimator, first motor control apparatus, and first robotic system.

A first notch filter includes: an attenuation filter configured to acquire a signal containing a vibrational component generated in association with rotation of a motor, to perform attenuation of the vibrational component; and an attenuation controller configured to control an attenuation amount in the attenuation, corresponding to a rotation speed of the motor.

In a second notch filter according to the first notch filter, the attenuation controller is configured to control a center frequency in an attenuation band of the attenuation, corresponding to a rotation speed of the motor.

In a third notch filter according to the first notch filter, the attenuation filter is configured to acquire the signal containing the vibrational component generated by a reducer in association with rotation of the motor.

In a fourth notch filter according to the third notch filter, the attenuation filter is configured to acquire the signal containing the vibrational component that changes corresponding to a rotation speed of the motor.

In a fifth notch filter according to the third notch filter, the attenuation filter is configured to acquire the signal containing the vibrational component generated by a harmonic reducer in association with rotation of the motor.

In a sixth notch filter according to the second notch filter, the attenuation controller is configured to change the center frequency to a frequency proportional to the rotation speed.

In a seventh notch filter according to the second notch filter, the attenuation controller is configured to change the center frequency to a frequency n times (n is an integer equal to or more than 2) as large as the rotation speed.

In an eighth notch filter according to the first notch filter, the attenuation controller is configured to set the attenuation amount to a constant amount larger than 0 irrespective of the rotation speed in a case where the rotation speed is equal to or more than a predetermined threshold value.

In a ninth notch filter according to the first notch filter, the attenuation controller is configured to: set the attenuation amount to 0 in a case where the rotation speed is equal to or less than a first threshold value; and set the attenuation amount to a constant amount larger than 0 irrespective of the rotation speed in a case where the rotation speed is equal to or more than a second threshold value larger than the first threshold value.

A first external force estimator includes: an external force observer configured to generate an external-force estimated value based on information related to a torque of a motor and information related to a rotation speed of a motor; and a notch filter configured to attenuate a vibrational component that is contained in the external-force estimated value output from the external force observer and generated in association with rotation of the motor. The notch filter includes: an attenuation filter configured to acquire the external-force estimated value to perform attenuation of the vibrational component; and an attenuation controller configured to control an attenuation amount of the attenuation corresponding to a rotation speed of the motor.

A first motor control apparatus includes: an attenuation filter configured to acquire a signal containing a vibrational component generated in association with rotation of a motor to perform attenuation of the vibrational component; and an attenuation controller configured to control an attenuation amount of the attenuation corresponding to a rotation speed of the motor.

A first robotic system includes: a robot configured such that respective joint portions include motors; an external force observer configured to generate an external-force estimated value based on information related to a torque of the motor and information related to a rotation speed of the motor; and a notch filter configured to attenuate a vibrational component that is contained in the external-force estimated value output from the external force observer and generated in association with rotation of the motor. The notch filter includes: an attenuation filter configured to acquire the external-force estimated value to perform attenuation of the vibrational component; and an attenuation controller configured to control an attenuation amount of the attenuation corresponding to a rotation speed of the motor.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is;:

1. A notch filter comprising:
an attenuation filter configured to acquire a signal containing a vibrational component generated in association with movement of a motor, to perform attenuation of the vibrational component; and
an attenuation controller configured to control an attenuation amount in the attenuation, corresponding to a movement speed of the motor.

2. The notch filter according to claim 1, wherein
the attenuation filter is configured to acquire the signal containing the vibrational component generated in association with rotation of a rotary motor as the motor to perform the attenuation of the vibrational component, and
the attenuation controller is configured to control an attenuation amount in the attenuation, corresponding to a rotation speed of the motor.

3. The notch filter according to claim 2, wherein
the attenuation controller is configured to control a center frequency in an attenuation band of the attenuation, corresponding to a rotation speed of the motor.

4. The notch filter according to claim 2, wherein
the attenuation filter is configured to acquire the signal containing the vibrational component generated by vibration of a reducer in association with rotation of the motor.

5. The notch filter according to claim 4, wherein
the attenuation filter is configured to acquire the signal containing the vibrational component that changes corresponding to a rotation speed of the motor.

6. The notch filter according to claim 4, wherein
the attenuation filter is configured to acquire the signal containing the vibrational component generated by vibration of a harmonic reducer as the reducer in association with rotation of the motor.

7. The notch filter according to claim 3, wherein
the attenuation controller is configured to change the center frequency to a frequency proportional to the rotation speed.

8. The notch filter according to claim 3, wherein
the attenuation controller is configured to change the center frequency to a frequency n times (n is an integer equal to or more than 2) as large as the rotation speed.

9. The notch filter according to claim 2, wherein
the attenuation controller is configured to set the attenuation amount to a constant amount larger than 0 irrespective of the rotation speed in a case where the rotation speed is equal to or more than a predetermined threshold value.

10. The notch filter according to claim 2, wherein
the attenuation controller is configured to: set the attenuation amount to 0 in a case where the rotation speed is equal to or less than a first threshold value; and set the attenuation amount to a constant amount larger than 0 irrespective of the rotation speed in a case where the rotation speed is equal to or more than a second threshold value larger than the first threshold value.

11. The notch filter according to claim 1, wherein
the attenuation filter is configured to acquire the signal containing the vibrational component generated in association with translation of a linear motor as the motor to perform the attenuation of the vibrational component, and
the attenuation controller is configured to control an attenuation amount in the attenuation, corresponding to a translational speed of the motor.

12. An external force estimator comprising:
the notch filter according to claim 1; and
an external force observer configured to generate an external-force estimated value based on information of the motor, the information being related to a movement force and related to a movement speed, wherein
the attenuation filter is configured to acquire the external-force estimated value output from the external force observer as the signal to perform the attenuation of the vibrational component.

13. An external force estimator comprising:
the notch filter according to claim 2; and
an external force observer configured to generate an external-force estimated value based on information of the motor, the information being related to a torque and related to a rotation speed, wherein
the attenuation filter is configured to acquire the external-force estimated value output from the external force observer as the signal to perform the attenuation of the vibrational component.

14. A motor control apparatus comprising the notch filter according to claim 1.

15. A motor control apparatus comprising the notch filter according to claim 2.

16. The motor control apparatus according to claim 15, further comprising a controller configured to control the motor based on a signal where the vibrational component is attenuated, the signal being output from the attenuation filter.

17. A robotic system comprising:
the notch filter according to claim 1;
a robot that includes a joint portion including the motor; and
an external force observer configured to generate an external-force estimated value based on information of the motor, the information being related to a movement force and related to a movement speed, wherein
the attenuation filter is configured to acquire the external-force estimated value as the signal, output from the external force observer, to perform the attenuation of the vibrational component.

18. A robotic system comprising:
the notch filter according to claim 2;
a robot that includes a joint portion including the motor; and
an external force observer configured to generate an external-force estimated value based on information of the motor related to a torque and related to a rotation speed, wherein
the attenuation filter is configured to acquire the external-force estimated value as the signal, output from the external force observer, to perform the attenuation of the vibrational component.

19. The robotic system according to claim 18, wherein
the robot includes a plurality of the joint portions,
each of the plurality of the joint portions includes the external force observer and the notch filter, and
the robotic system further comprises a subsequent-stage notch filter disposed in a subsequent stage of the notch filter in one of the joint portions, the subsequent-stage notch filter being configured to attenuate a vibrational component contained in a signal output from the notch filter, the signal being generated in association with rotation of the motor in another of the joint portions.

20. A notch filter comprising:
means for filtering to perform attenuation of a vibrational component contained in a signal and generated in association with movement of a motor; and
means for controlling an attenuation amount of the attenuation, corresponding to a movement speed of the motor.
